(19) United States
(12) Patent Application Publication
(10) Pub. No.: US 2011/0090015 A1
(43) Pub. Date: Apr. 21, 2011

(54) SEMICONDUCTOR INTEGRATED CIRCUIT AND ELECTRONIC DEVICE

(75) Inventors: Masaya Sumita, Hyogo (JP); Keiichi Fujimoto, Kyoto (JP)

(73) Assignee: PANASONIC CORPORATION, Osaka (JP)

(21) Appl. No.: 12/979,976

(22) Filed: Dec. 28, 2010

Related U.S. Application Data
(63) Continuation of application No. PCT/JP2009/001161, filed on Mar. 16, 2009.

(30) Foreign Application Priority Data
Sep. 30, 2008 (JP) 2008-255236

(51) Int. Cl. H03K 3/354

(52) U.S. Cl. 331/56

(57) ABSTRACT

A semiconductor integrated circuit includes a first ring oscillator to which a stress voltage is applied; a second ring oscillator to which the stress voltage is not applied; and a phase comparator configured to receive an output of the first ring oscillator and an output of the second ring oscillator, and to compare phases of the outputs. The first ring oscillator includes a switch circuit configured to switch between a first connection state in which ring connection of the first ring oscillator is disconnected to connect a predetermined node of the second ring oscillator to a predetermined node of the first ring oscillator, and a second connection state in which connection between the first ring oscillator and the second ring oscillator is disconnected to connect the first ring oscillator in a ring.

### CROSS-REFERENCE TO RELATED APPLICATION

This is a continuation of PCT International Application PCT/JP2009/001161 filed on Mar. 16, 2009, which claims priority to Japanese Patent Application No. 2008-255236 filed on Sep. 30, 2008. The disclosures of these applications including the specifications, the drawings, and the claims are hereby incorporated by reference in their entirety.

### BACKGROUND

The present disclosure relates to semiconductor integrated circuits and electronic devices, and more particularly to measurement of degradation in characteristics of MOSFETs forming semiconductor integrated circuits.

As miniaturization technology of semiconductor manufacture progresses, gate lengths of MOSFETs in semiconductor integrated circuits have been reduced to tens of nanometers, and thicknesses of gate oxide films have been reduced to 2 nm or less. Latest MOSFETs realize high currents and low leakage currents by using a high dielectric material for a gate oxide film, and a metal electrode for a gate electrode.

On the other hand, reliability of such miniaturized MOSFETs are becoming problematic. One of the problems is degradation in current characteristics of a MOSFET. Specifically, it is a phenomenon in which a current amount is reduced by using a MOSFET. In order to understand the mechanism, analyses are performed by various analytical methods. (See, for example, Mahapatra S., Alam M. A., A Predictive Reliability Model for PMOS Bias Temperature Degradation, Electron Devices, International Electron Devices Meeting 2002, pp. 505-508; V. Reddy, A. Krishnan, A. Marshal, et al., Impact of Negative Bias Temperature Instability on Digital Circuit Reliability, IRPS, 2002, pp. 248-254; G. Ribes et al., Review on High-K Dielectrics Reliability Issues, Device and Materials Reliability, IEEE Transactions on Volume 5, Issue 1, March 2005, pp. 5-19; and T. Kim et al., Silicon Odometer: An On-Chip Reliability Monitor for Measuring Frequency Degradation of Digital Circuits, Symposium on VLSI Circuits Digest of Technical Papers, 2007, pp. 122-123 (hereinafter referred to as “Kim et al.”).)

As significant degradation in characteristics of a miniaturized CMOS process, there are degradation in bias temperature instability (BTI) and degradation in dielectric breakdown. The degradation in the BTI is classified into two types: degradation in negative bias temperature instability (NBTI) and degradation in positive bias temperature instability (PBTI). The degradation in the NBTI is a phenomenon in which the absolute value of a threshold voltage of a transistor gradually increases so that speed of the transistor decreases as time progresses, when the temperature of a chip increases with a substrate potential back-biased with respect to a gate potential. The degradation in the PBTI is a phenomenon in which the absolute value of a threshold voltage of a transistor gradually increases so that speed of the transistor decreases as time progresses, when the temperature of a chip increases with a substrate potential forward-biased with respect to a gate potential.

The degradation in the dielectric breakdown is caused by breakdown of a gate oxide film. There are various types of breakdown of a gate oxide film. For example, there are breakdown in which a MOSFET does not operate suddenly in use (i.e., hard breakdown (HBD)), and breakdown in which a leakage current between a gate and a substrate is little at an early stage but gate leakage slightly increases as time progresses (i.e., soft breakdown (SBD), and progressive breakdown (PBD). These types are called “time dependent dielectric breakdown (TDDB).” The degradation in the TDDB varies depending on the length and the area of a wire connected to a gate of a MOSFET. Moreover, in wire formation, when a thin film is formed by CVD or PVD, and then the surface of the wire is planarized by chemical mechanical polishing (CMP) etc., the wire is electrically charged to influence a gate electrode. This is called an “antenna effect.” In actual semiconductor integrated circuits, appropriate measures are taken such as division of tasks for making it difficult to cause degradation in characteristics of MOSFETs, or detection or measurement of degradation in the characteristics of the MOSFETs. (See, for example, Japanese Patent Publication No. 2006-074746, Japanese Patent Publication No. 2008-147245, and A. Leon et al., A Power-Efficient High-Throughput 32-Thread SPARC Processor, ISSCC 2006 S5.1, 641, pp. 98-99 (hereinafter referred to as “Leon et al.”).)

### SUMMARY

As a method of detecting or measuring degradation in characteristics of a MOSFET, there are (1) a method of detecting a frequency of a ring oscillator (see, for example, T. Kim, et al.), and (2) a method of detecting whether or not delay time of a logic chain formed by flip flops is within a predetermined clock cycle (see, for example, Japanese Patent Publication No. 2008-147245). These methods have the following problems.

In the case of the ring oscillator type, an external noise causes jitter in an output of the ring oscillator, leading to a measurement error. The noise causes other noises due to negative feedback. The band of noise generation ranges from a low frequency of about 30 kHz to a high frequency of tens of GHz. In an empirical measurement, jitter ranges from about 300 psec to about 1 nsec at 3σ. The distribution of jitter is not always a Gaussian distribution. The distribution of jitter may be flat due to, e.g., impedance matching of a power supply and a probe, or may be discrete due to spurious noise. FIGS. 14 and 15 illustrate simulation results of jitter spectra where inductances of 10 nH and 1 nH are applied to a power supply of a 19-stage ring oscillator, respectively. It is found from the simulation results that about 300 psec of jitter exists in σ. Moreover, jitter values and distribution shapes vary depending on inductance values. Even when a frequency of an output of a ring oscillator is divided and the divided frequency is measured, the result does not necessarily indicate the mean value of the oscillation frequencies of the ring oscillator. The jitter distribution varies depending on a difference in a mask pattern of the ring oscillator (e.g., a difference in an additional structure of an antenna). Therefore, a measurement error is caused by a difference in a mask pattern, contact with a probe, and power supply impedance.

On the other hand, in the case of the chain type, a circuit for minutely changing a clock signal cycle is required to highly accurately detect and measure degradation in characteristics of a MOSFET. Such a circuit cannot be realized due to variations of elements in a conventional digital circuit. The circuit needs to include a DLL circuit having a function of feedback. However, if the DLL circuit is mounted, overhead of the circuit area increases and control becomes complex.

Moreover, as described above, appropriate measures are taken by detecting or measuring degradation in characteristics of a MOSFET. For example, in the technique shown in Japanese Patent Publication No. 2008-147245, degradation in characteristics of a MOSFET is detected and measured by a chain type. However, there arises a problem that control is complex. The technique shown in Leon et al. detects only temperatures, and thus, can detect degradation in BTI. However, Leon et al. has difficulty in detecting degradation in other types of TDDB.

A semiconductor integrated circuit according to an embodiment of the present disclosure includes a first ring oscillator to which a stress voltage is applied; a second ring oscillator to which the stress voltage is not applied; and a phase comparator configured to receive an output of the first ring oscillator and an output of the second ring oscillator, and to compare phases of the outputs. The first ring oscillator includes a switch circuit configured to switch between a first connection state in which ring connection of the first ring oscillator is disconnected to connect a predetermined node of the second ring oscillator to a predetermined node of the first ring oscillator, and a second connection state in which connection between the first ring oscillator and the second ring oscillator is disconnected to connect the first ring oscillator in a ring.

This enables high accuracy measurement of a phase difference between the outputs of the first and second ring oscillators without being influenced by jitter etc. Therefore, degradation in characteristics of a MOSFET in the first ring oscillator after being subject to stress can be highly accurately measured.

Preferably, the above semiconductor integrated circuit further includes a current comparator configured to compare a current consumed in the first ring oscillator and a current consumed in the second ring oscillator, where supply of power supply voltages to the first and second ring oscillators is stopped.

With this feature, a difference between consumed currents of the first and second ring oscillators can be measured when supply of power supply voltages is stopped, thereby enabling measurement of a gate leakage current due to degradation in the characteristics of the MOSFET. Therefore, it can be determined whether the degradation in the characteristics of the MOSFET is caused by degradation in TDDB or degradation in BTI.

Specifically, the first and second ring oscillators are configured to control supply of power supply voltages independently from each other. Moreover, each of the first and second ring oscillators stops oscillating upon receipt of a reset signal.

The first ring oscillator may include a gate capacitor corresponding to an antenna wire included in the second ring oscillator. Alternatively, the first and second ring oscillators may include antenna wires having the same shapes. These configurations enable measurement of degradation in the characteristics of the MOSFET caused by an antenna effect.

An electronic device according to another embodiment of the present disclosure includes a plurality of semiconductor integrated circuits, a power supply voltage determination section, and a power supply voltage supply section. Each of the semiconductor integrated circuits includes a ring oscillator, a function block including an inverter chain, a phase comparator configured to receive an output of the function block and an output of the ring oscillator, and to compare phases of the outputs, and a comparator configured to compare an output of the phase comparator and a reference value. The function block includes a switch circuit configured to switch between a first connection state in which the inverter chain is disconnected from the function block to be connected to a predetermined node of the ring oscillator, and a second connection state in which the inverter chain is disconnected from the ring oscillator to be connected to the function block. The power supply voltage determination section determines a power supply voltage to be supplied to each of the plurality of semiconductor integrated circuits based on a comparison result of the comparator in each of the plurality of semiconductor integrated circuits. The power supply voltage supply section supplies a power supply voltage to the function block of each of the plurality of semiconductor integrated circuits in accordance with the determination of the power supply voltage determination section.

This controls power supply voltages to be supplied to the semiconductor integrated circuits in accordance with a measurement result of degradation in characteristics of the MOSFETs of the semiconductor integrated circuits. Therefore, an increase in lifetime, high-speed operation, miniaturization, and a decrease in power consumption of the electronic device can be achieved.

### BRIEF DESCRIPTION OF THE DRAWINGS

FIG. 1 is a configuration diagram of a semiconductor integrated circuit according to a first embodiment.

FIG. 2 is a detailed configuration diagram of a part formed by two ring oscillators.

FIG. 3 is a circuit configuration diagram of a tri-state inverter.

FIG. 4 is a circuit configuration diagram of a tri-state inverter.

FIG. 5 is a circuit configuration diagram of a phase comparison circuit in a phase comparator.

FIG. 6 is a circuit configuration diagram of a charge pump circuit in the phase comparator.

FIG. 7 is a timing diagram of the semiconductor integrated circuit according to the first embodiment.

FIG. 8 illustrates a simulation result of jitter of a phase difference between inputs of the phase comparator.

FIG. 9 is a detailed configuration diagram of a part formed by two ring oscillators, where antenna wires are included.

FIG. 10 is a configuration diagram of a semiconductor integrated circuit according to a second embodiment.

FIG. 11 is a circuit configuration diagram of a current comparator.

FIG. 12 is a timing diagram of the semiconductor integrated circuit according to the second embodiment in a degradation measurement mode.

FIG. 13 is a configuration diagram of an electronic device according to a third embodiment.

FIG. 14 illustrates a simulation result of a jitter spectrum where an inductance of 10 nH is applied to a power supply of a 19-stage ring oscillator.

FIG. 15 illustrates a simulation result of a jitter spectrum where an inductance of 1 nH is applied to the power supply of the 19-stage ring oscillator.

### DETAILED DESCRIPTION

### First Embodiment

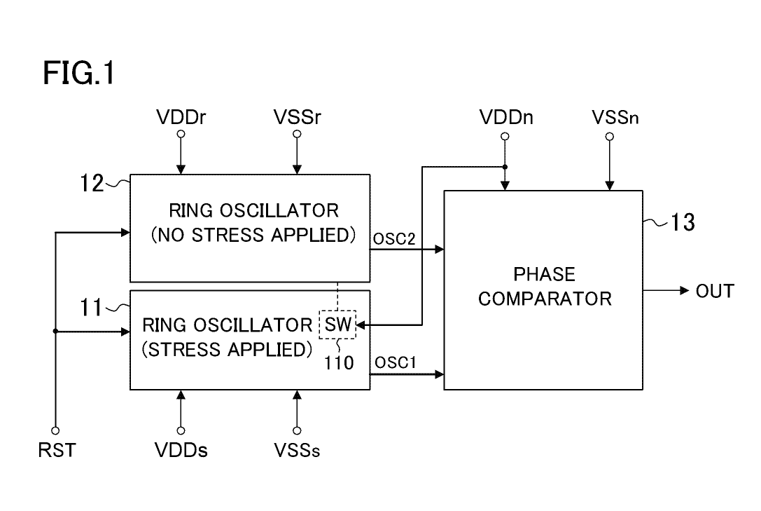

FIG. 1 illustrates a configuration of a semiconductor integrated circuit according to a first embodiment. Each of ring oscillators 11 and 12 includes an inverter ring having the same number of stages. Signals VDDs and VSSs are supplied to the ring oscillator 11 as a power supply voltage and a ground voltage, respectively. Signals VDDr and VSSr are supplied to the ring oscillator 12 as a power supply voltage and a ground voltage, respectively. Each of the ring oscillators 11 and 12 stops oscillating upon receipt of a reset signal RST. Note that, as described later, a signal VDDs having a stress voltage higher than a normal power supply voltage may be supplied to the ring oscillator 11. That is, the ring oscillator 11 is configured to be applied with a stress voltage, and the ring oscillator 12 is configured not to be applied with a stress voltage.

In the ring oscillator 11, a switch circuit 110 switches between a first connection state in which ring connection of the ring oscillator 11 is disconnected to connect a predetermined node of the ring oscillator 12 to a predetermined node of the ring oscillator 11, and a second connection state in which connection between the ring oscillator 11 and the ring oscillator 12 is disconnected to connect the ring oscillator 11 in a ring. Specifically, the switch circuit 110 switches between the first connection state and the second connection state in accordance with a signal VDDn.

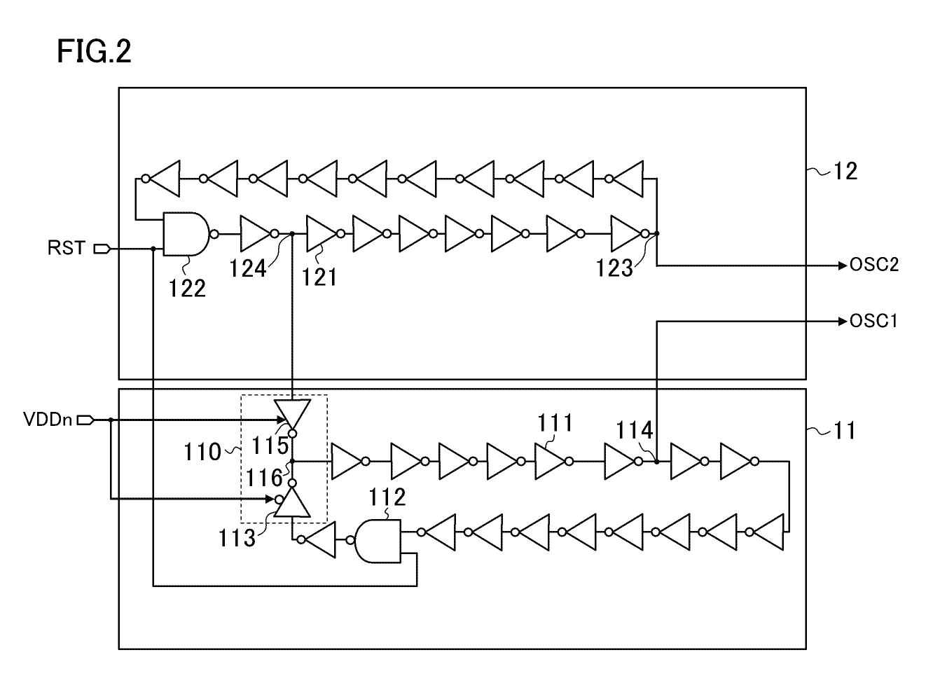

FIG. 2 illustrates a detailed configuration of a part formed by the ring oscillators 11 and 12. The ring oscillator 11 includes seventeen inverters 111, a NAND gate 112 to which the reset signal RST is input, and a tri-state inverter 113 controlled by the signal VDDn; which are connected in a ring. The ring oscillator 11 outputs an oscillation signal OSC1 from a node 114. The ring oscillator 12 includes eighteen inverters 121, and a NAND gate 122 to which the reset signal RST is input; which are connected in a ring. The ring oscillator 12 outputs an oscillation signal OSC2 from a node 123. As such, the ring oscillators 11 and 12 can operate as 19-stage ring oscillators.

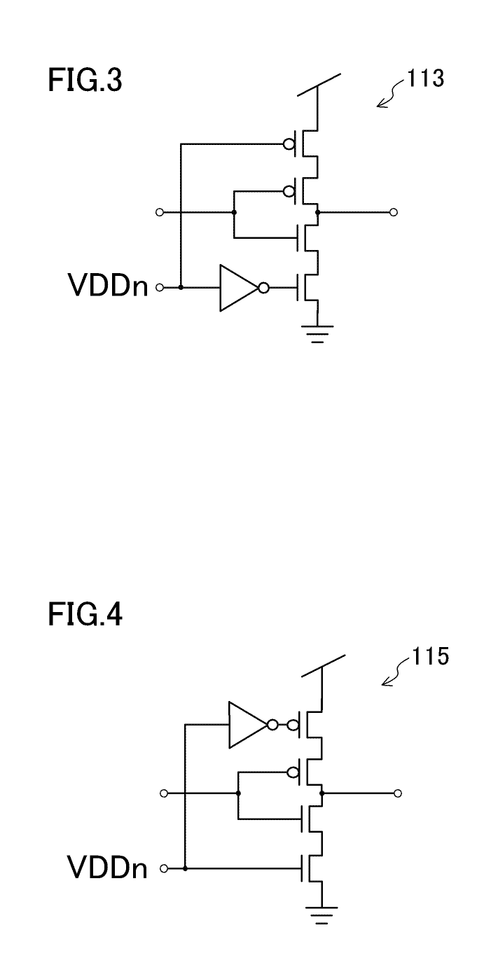

The switch circuit 110 includes the tri-state inverter 113, and an tri-state inverter 115. The tri-state inverter 115 is connected between a node 116 of the ring oscillator 11 and a node 124 of the ring oscillator 12. FIGS. 3 and FIG. 4 illustrate circuit configurations of the tri-state inverters 113 and 115. When the signal VDDn is at a high potential, the tri-state inverter 113 is open, the tri-state inverter 115 operates as an inverter, and the switch circuit 110 is in the first connection state. On the other hand, when the signal VDDn is at a low potential, the tri-state inverter 113 operates as an inverter, the tri-state inverter 115 is open, and the switch circuit 110 is in the second connection state.

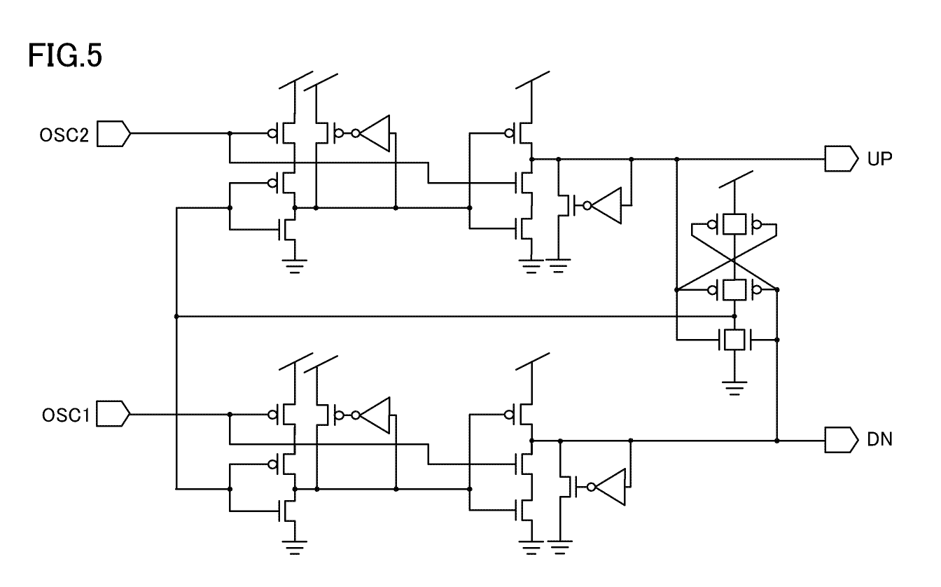

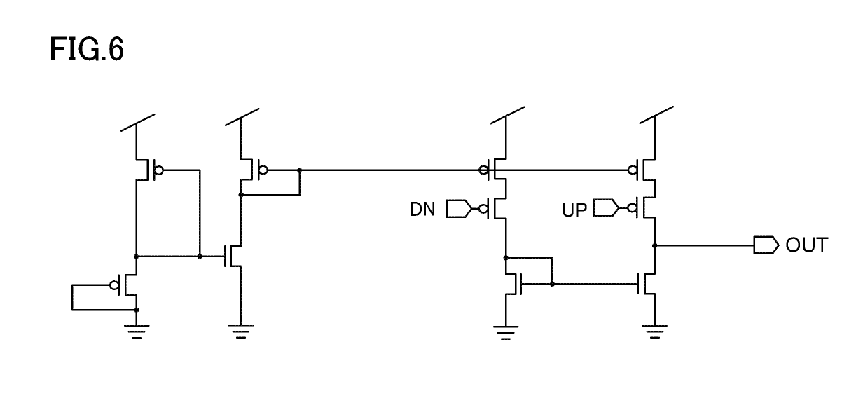

Referring back to FIG. 1, a phase comparator 13 receives the oscillation signals OSC1 and OSC2, compares the phases of these signals, and outputs a signal OUT indicating the result of the phase comparison. The signal VDDn and a signal VSSn are supplied to the phase comparator 13 as a power supply voltage and a ground voltage, respectively. Specifically, the phase comparator 13 includes two circuits of a phase comparison circuit (see FIG. 5) for generating signals UP and DN indicating lead/lag of rising transition timing of the oscillation signal OSC2 using the rising transition timing of the oscillation signal OSC2 as a reference, and a charge pump circuit (see FIG. 6) for pushing and pulling a current (i.e., the signal OUT) based on the signals UP and DN.

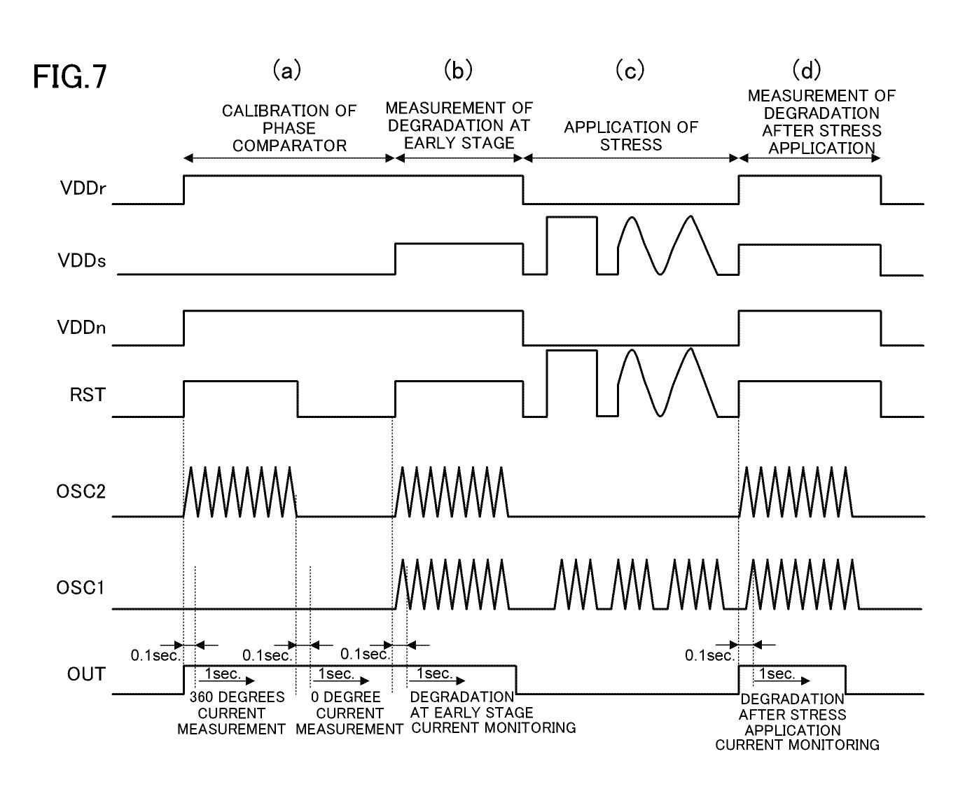

Next, measurement of degradation in characteristics of a MOSFET in the semiconductor integrated circuit according to this embodiment will be described below with reference to a timing diagram of FIG. 7. The measurement of degradation in the characteristics of a MOSFET is divided into four stages of: (a) calibration of the phase comparator 13, (b) measurement of degradation at an early stage, (c) application of stress, and (d) measurement of degradation after the stress application. The following table illustrates the relationship between operation modes and signal voltages in the semiconductor integrated circuit according to this embodiment.

TABLE 1

| | SIGNAL | | | | | | | |
|---|---|---|---|---|---|---|---|---|
| MODE | RST | VSSr | VDDr | VDDs | VSSs | VDDn | VSSn | OUT |
| CALIBRATION OF | STOPS AT 0 V | 0 V | 1.8 V | 0 V | 0 V | 1.8 V | 0 V | 0.9 V |
| PHASE COMPARATOR | OSCILLATES | | | | | | | (CURRENT |
| | AT 1.8 V | | | | | | | OUTPUT) |
| MEASUREMENT | STOPS AT 0 V | 0 V | 1.8 V | 1.8 V | 0 V | 1.8 V | 0 V | 0.9 V |
| OF DEGRADATION | OSCILLATES | | | | | | | (CURRENT |
| | AT 1.8 V | | | | | | | OUTPUT) |
| STRESS | STOPS AT 0 V | 0 V | 0 V | STRESS | 0 V | 0 V | 0 V | 0 V |
| APPLICATION | OSCILLATES | | | VOLTAGE | | | | (0 A) |
| | AT STRESS | | | | | | | |
| | VOLTAGE | | | | | | | |

At the first stage, calibration of the phase comparator 13 is performed to set a reference value for measuring degradation in the characteristics of the MOSFET at the following stages. The first stage is further divided into two stages. One is measurement of the signal OUT where the phase difference between outputs of the ring oscillators 11 and 12 is maximum, and the other is measurement of the signal OUT where the phase difference between the outputs is zero. Specifically, in the former measurement, the signals VDDr, VDDn, and RST are set to 1.8 V, and the signal VDDs is set to 0 V. As a result, the ring oscillator 12 is in an oscillation state, and the ring oscillator 11 is in a stopped state. Thus, the phase difference between outputs of the ring oscillators 11 and 12 becomes maximum, and the signal OUT also becomes maximum. On the other hand, in the latter measurement, the reset signal RST is set to 0V. As a result, the ring oscillator 12 is in a stopped state. Thus, the phase difference between the outputs of the ring oscillators 11 and 12 is zero, and the signal OUT is minimum.

At the second stage, degradation in the characteristics of the MOSFET in the ring oscillator 11 at an earlier stage, i.e., before being applied with stress is measured. Specifically, at the second stage, the signals VDDr, VDDs, VDDn, and RST are set to 1.8 V. As a result, the ring oscillator 12 oscillates. On the other hand, the ring connection of the ring oscillator 11 is disconnected, and an inverter chain being a part of the ring connection is connected to the ring oscillator 12. Thus, the difference between signal delay of the 7-stage inverter chain (see FIG. 2) in the ring oscillator 11 including the tri-state inverter 115 and six of the inverters 111 between the node 116 and the node 114, and signal delay of the 7-stage inverter chain (see FIG. 2) in the ring oscillator 12 including seven of the inverters 121 between the node 124 to the node 123 is the phase difference between outputs of the ring oscillators 11 and 12. The signal OUT is set to a value according to the phase difference between the outputs.

At the third stage, stress is applied to the ring oscillator 11. Specifically, at the third stage, the signals VDDs and RST are set to a stress voltage which is higher than 1.8 V of a normal power supply voltage. The signals VDDr and VDDn are set to 0 V so that the ring oscillator 12 and the phase comparator 13 are not subject to stress. As a result, the ring oscillator 12 is in a stopped state, while the ring oscillator 11 is in an oscillation state under the stress application. The signals VDDn and RST may have any waveform, and may be either of DC or AC signals.

At the fourth stage, degradation in the characteristics of the MOSFET after applying the stress is measured. The conditions of the signals are the same as those at the second stage. Note that the signal VDDs may be held at a high potential in the transition from the third stage to the fourth stage. This enables measurement of the degradation in the characteristics of the MOSFET on the fly.

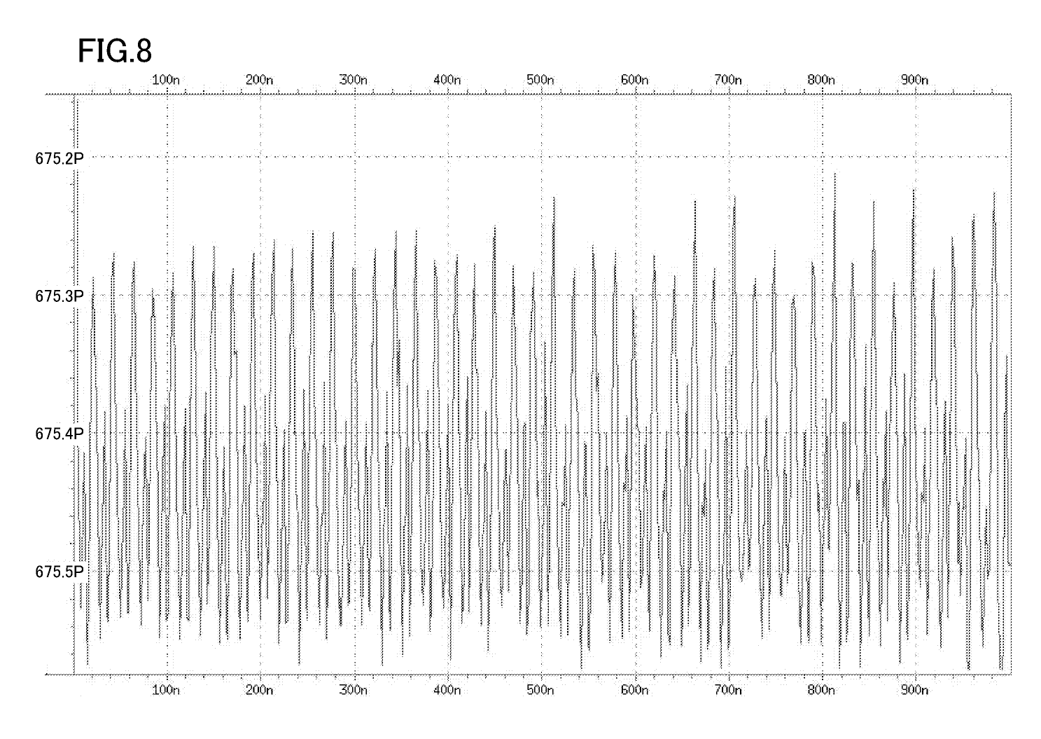

As described above, this embodiment employs means for measuring degradation in characteristics of a MOSFET using the phase difference between outputs of the ring oscillators 11 and 12 as a reference. The measurement errors of the ring oscillators 11 and 12 caused by jitter are slight. FIG. 8 illustrates a simulation result of jitter of a phase difference between inputs of the phase comparator 13. The jitter of the phase difference is only about 0.2 psec. Moreover, since the ring oscillators 11 and 12 have the same probe contact and the same power supply impedance, there is little measurement error caused by the probe contact and the power supply impedance. Thus, compared to a conventional ring oscillator type, degradation in characteristics of a MOSFET can be measured with extremely high accuracy. According to this embodiment, degradation in characteristics of a MOSFET can be highly accurately measured only by controlling the switch circuit 110. Therefore, compared to a conventional chain type, the semiconductor integrated circuit of this embodiment requires only a small circuit configuration, since there is no need to provide a complex circuit such as a clock phase generation circuit.

Note that time of a phase difference can be clearly detected by measuring the frequency of the oscillation signal OSC2 after being divided by a frequency divider etc. A capacitor with a switch may be connected to a node of each of the ring oscillators 11 and 12 to switch between connection and disconnection of the node to the capacitor by controlling the switch. This enables measurement of degradation in the characteristics of the MOSFET at various oscillation frequencies.

### Variation

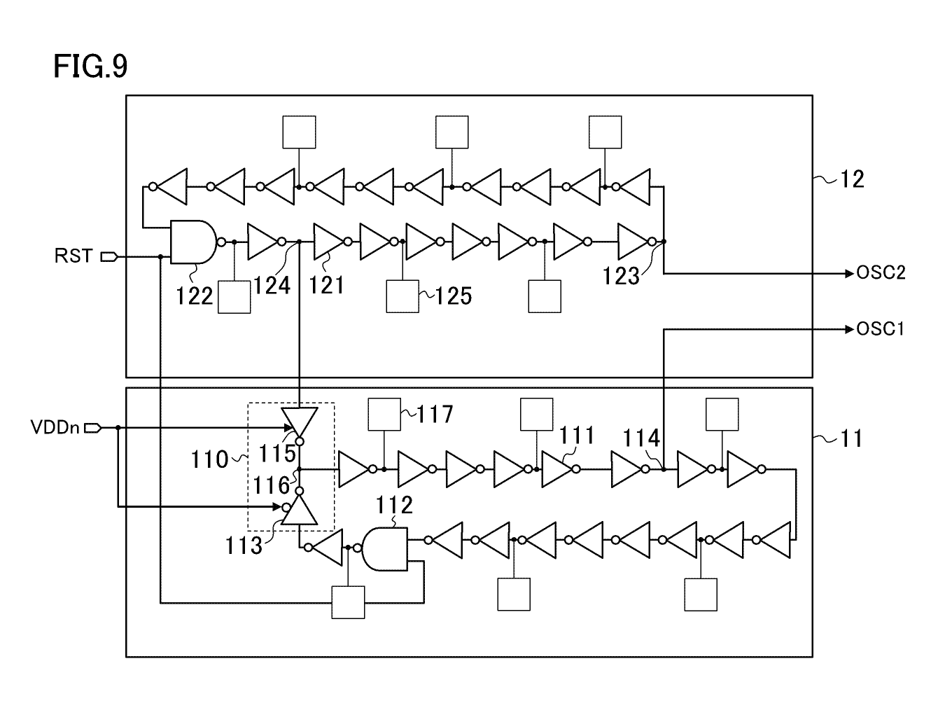

When a node of the ring oscillator 11 is connected to an antenna wire, a corresponding node of the ring oscillator 12 may be connected to a gate capacitor having the same capacitance as the antenna wire. FIG. 9 is a detailed configuration diagram of a part formed by the ring oscillators 11 and 12, where antenna wires are included. Antenna wires 117 are connected to positions of the ring oscillator 11. Accordingly, gate capacitors 125 are connected to positions of the ring oscillator 12. In the ring oscillator 11, degradation in the characteristics occurs in a gate electrode of the MOSFET due to an antenna effect. On the other hand, with respect to the MOSFET of the ring oscillator 12, since the characteristics of the gate capacitors 125 are not degraded by the antenna effect, degradation in the characteristics does not occur in the gate electrode of the MOSFET. Therefore, degradation in the characteristics of the MOSFET caused by the antenna effect can be measured by implementing the first to fourth stages.

When the gate lengths of the gate capacitors 125 are equal to the gate lengths of the MOSFETs forming the ring oscillators 11 and 12, degradation in BTI of the gate capacitors 125 can be equal to degradation in BTI of the MOSFETs. This is effective when a material for reducing the degradation in the BTI is added to the MOSFETs. On the other hand, when the gate lengths of the gate capacitors 125 are larger than the gate lengths of the MOSFETs forming the ring oscillators 11 and 12, degradation in the BTI of the gate capacitors 125 can be sufficiently reduced to a negligible amount compared to degradation in the BTI of the MOSFETs. This is effective when a material for reducing the degradation in the BTI is not added to the MOSFETs.

Note that the ring oscillator 12 may have antenna wires having the same shapes as the antenna wires 117 in the ring oscillator 11 instead of the gate capacitors 125. This enables analysis where BTI stress is applied to one of two ring oscillators influenced by similar antenna effects, and no BTI stress is applied to the other. As a result, a difference between degradation amounts in cases with and without BTI stress can be accurately measured.

### Second Embodiment

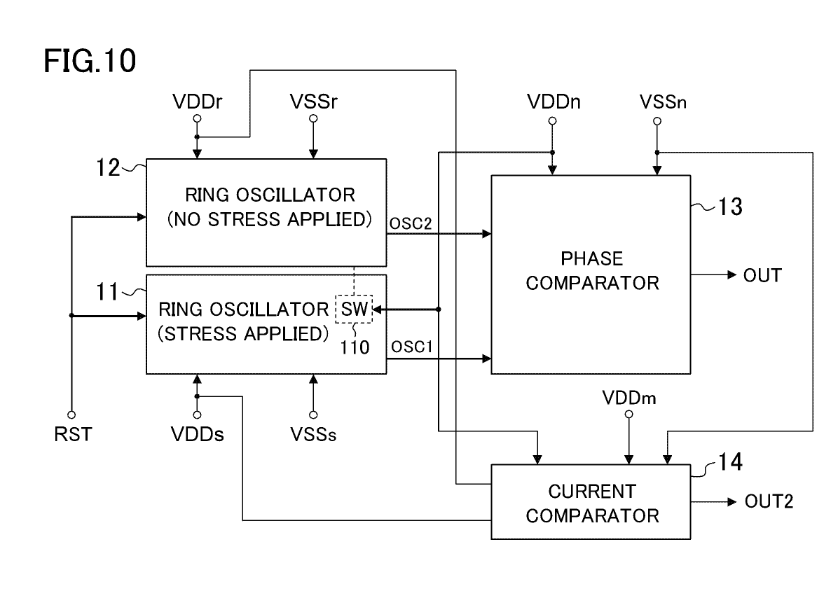

FIG. 10 illustrates a configuration of a semiconductor integrated circuit according to a second embodiment. The semiconductor integrated circuit according to this embodiment includes a current comparator 14 in addition to the semiconductor integrated circuit according to the first embodiment. The features different from the first embodiment will be described below.

The current comparator 14 operates with a signal VDDm having a higher voltage than the signal VDDn. When supply of a power supply voltage to the ring oscillators 11 and 12 is stopped, the current comparator 14 compares a current consumed in the ring oscillator 11 and a current consumed in the ring oscillator 12.

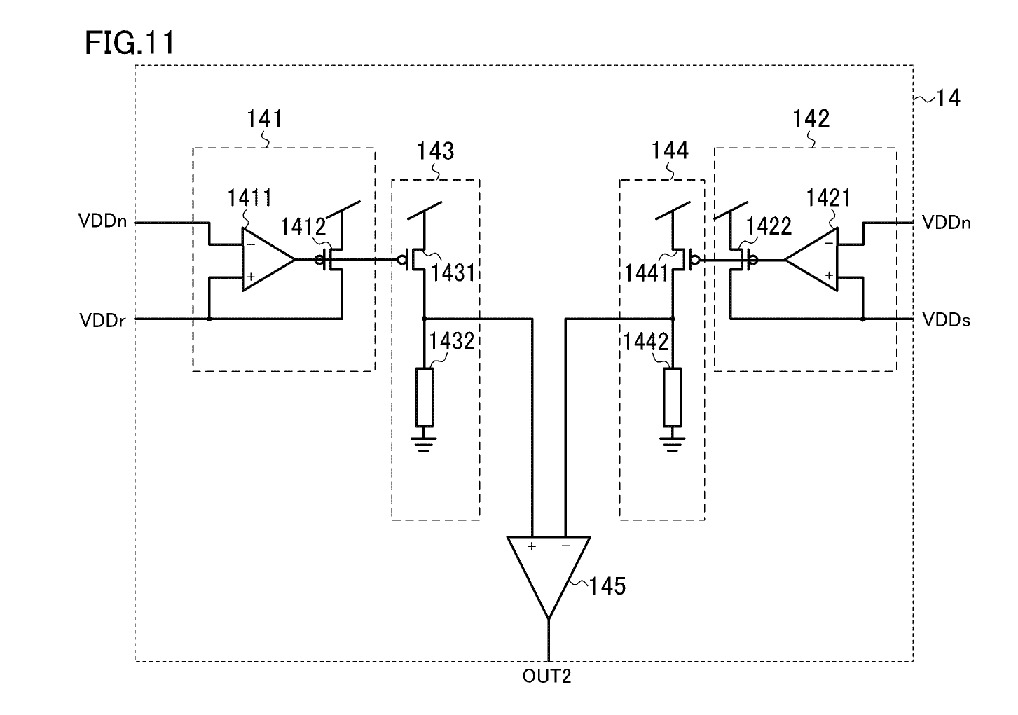

FIG. 11 illustrates a circuit configuration of the current comparator 14. In a voltage step-down circuit 141, the signals VDDn and a power line of the ring oscillator 11 are input to an operational amplifier 1411. In a PMOSFET 1412, the source is connected to the signal VDDm, the gate is connected to an output of the operational amplifier 1411, and the drain is connected to the power line of the ring oscillator 11. That is, the voltage step-down circuit 141 operates so that the signal VDDn is at the same potential as the power line of the ring oscillator 11. Similarly, in a voltage step-down circuit 142, the signals VDDn and a power line of the ring oscillator 12 are input to an operational amplifier 1421. In a PMOSFET 1422, the source is connected to the signal VDDm, the gate is connected to an output of the operational amplifier 1421, and the drain is connected to the power line of the ring oscillator 12. That is, the voltage step-down circuit 142 operates so that the signal VDDn is at the same potential as the power line of the ring oscillator 12. In a PMOSFET 1431 of a current-voltage conversion circuit 143, the source is connected to the signal VDDm, the gate is connected to the gate of the PMOSFET 1412, and the drain is connected to a resistor 1432. A current substantially proportional to a source-drain current of the PMOSFET 1412 flows to the PMOSFET 1431 and the resistor 1432. Similarly, in a PMOSFET 1441 of a current-voltage conversion circuit 144, the source is connected to the signal VDDm, the gate is connected to the gate of the PMOSFET 1422, and the drain is connected to a resistor 1442. A current substantially proportional to a source-drain current of the PMOSFET 1422 flows to the PMOSFET 1441 and the resistor 1442. An operational amplifier 145 compares a voltage generated at the resistor 1432 and a voltage generated at the resistor 1442, and outputs an signal OUT2.

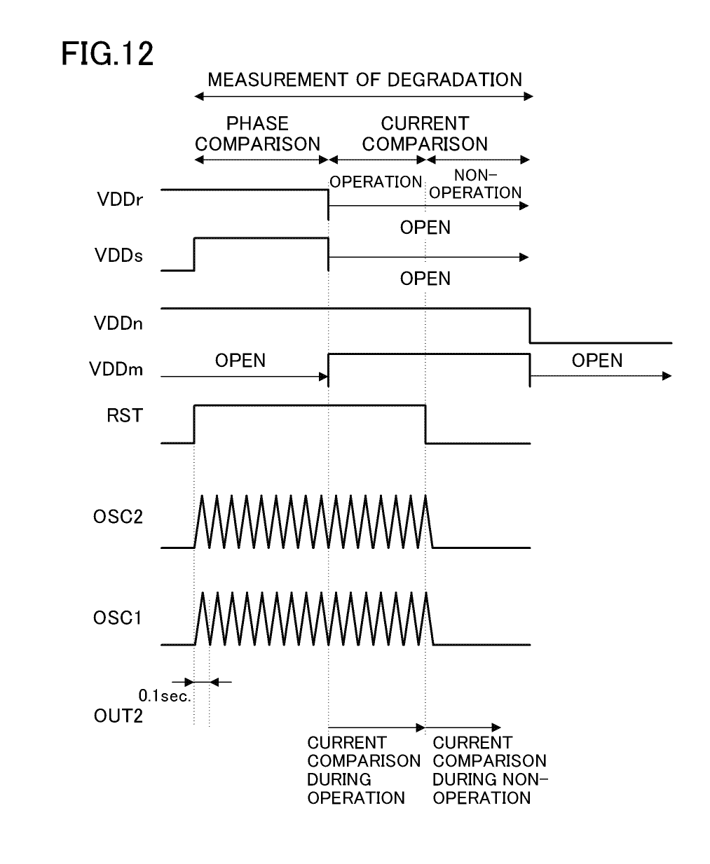

Next, operation of the semiconductor integrated circuit according to this embodiment in a degradation measurement mode will be described below with reference to a timing diagram of FIG. 12. First, phases of outputs of the ring oscillators 11 and 12 are compared. During the phase comparison, there is no need to supply the signal VDDm to the current comparator 14. Then, while the signals VDDr and VDDs are open to stop supplying power supply voltages to the ring oscillators 11 and 12, a current consumed in the ring oscillator 11 and a current consumed in the ring oscillator 12 are compared. During the current comparison, the signal VDDm is supplied to the current comparator 14. The current comparison is further divided into two stages of: comparison with the ring oscillators 11 and 12 oscillating, and comparison with the ring oscillators 11 and 12 stopped. The former stage is performed with the reset signal RST set at a high potential, and the latter stage is performed with the reset signal RST set at a low potential. After the current comparison, the signal VDDm is open, since there is no need to supply the signal VDDm to the current comparator 14.

As described above, in this embodiment, a difference between consumed currents where the ring oscillators 11 and 12 operates, and a difference between consumed currents where the ring oscillators 11 and 12 are stopped can be measured. Since an increase and a decrease of a gate leakage current can be measured by current comparison in a stopped state, it can be determined whether degradation in the characteristics of the MOSFET is caused by degradation in TDDB or degradation in BTI.

### Third Embodiment

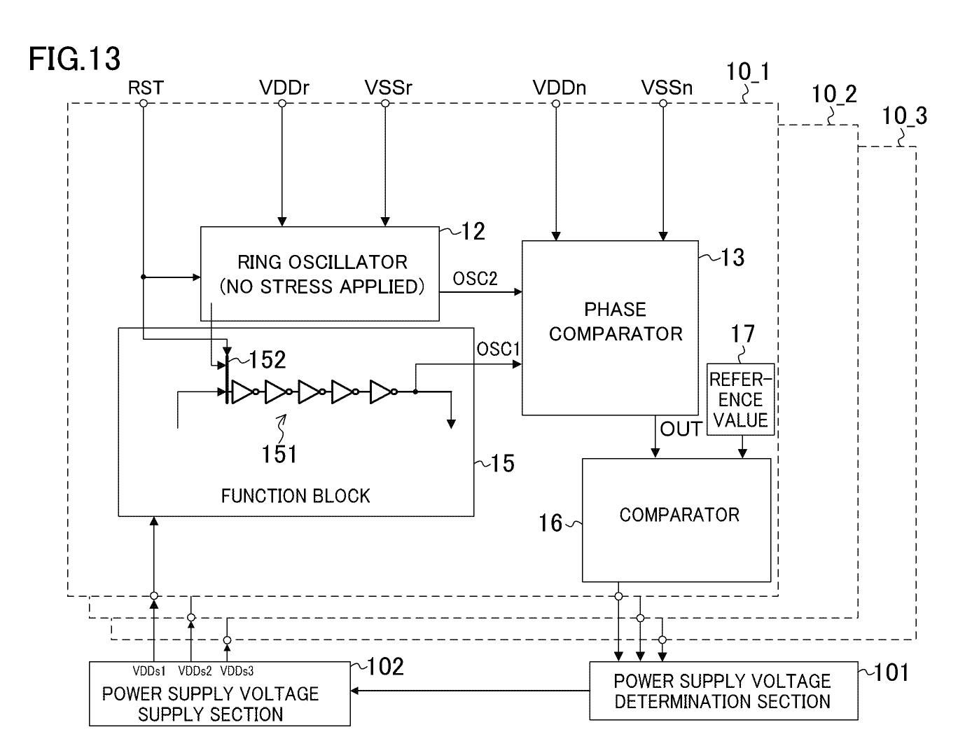

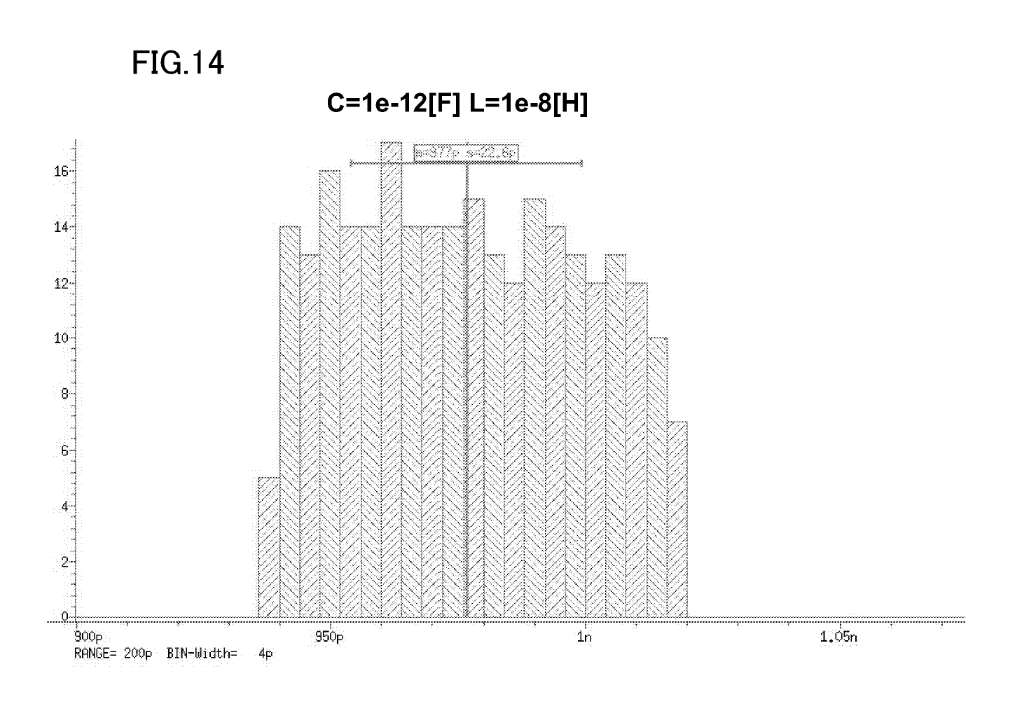

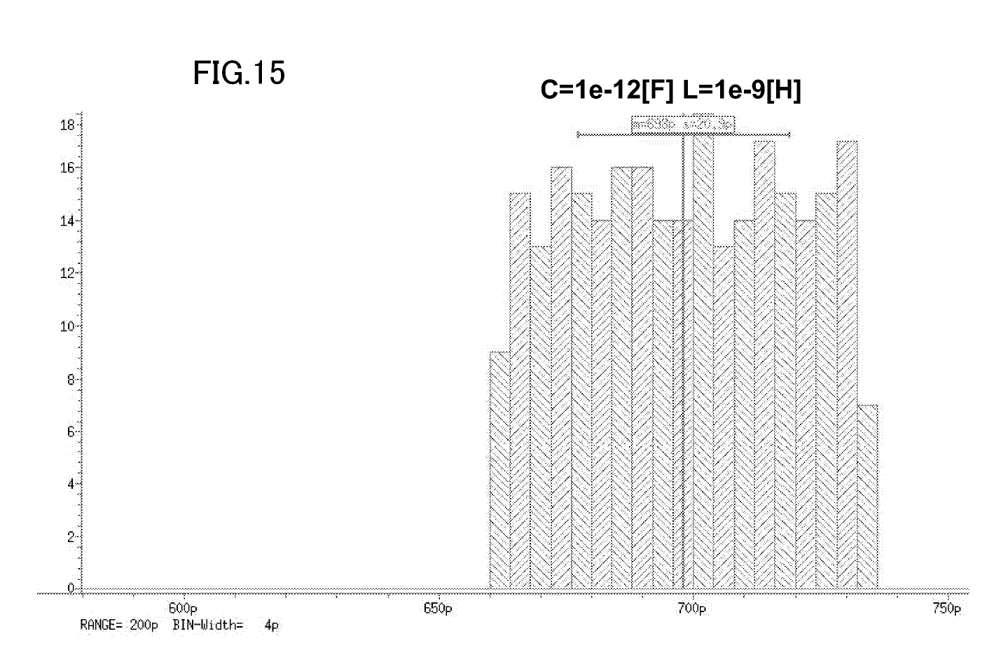

FIG. 13 illustrates a configuration of an electronic device according to a third embodiment. Semiconductor integrated circuits 10_1, 10_2, and 10_3 are, for example, a system-on-chip, a microprocessor, and a processing element in a chip. Each of the semiconductor integrated circuits 10_1-10_3 includes a ring oscillator 12, a phase comparator 13, a function block 15, and a comparator 16. The ring oscillator 12 and the phase comparator 13 are as described above.

Signals VDDs1, VDDs2, and VDDs3 are input to the function blocks 15 of the semiconductor integrated circuits 10_1-10_3 as power supply voltages. The phase comparator 13 receives the oscillation signal OSC2 of the ring oscillator 12, and the oscillation signal OSC1 of the function block 15; compares the phases of the signals; and outputs a signal OUT indicating the result of the phase comparison. The comparator 16 compares the signal OUT output from the phase comparator 13 and a reference value 17. The function block 15 includes an inverter chain 151. A switch circuit 152 switches between a first connection state in which the inverter chain 151 is disconnected from the function block 15 to be connected to a predetermined node of the ring oscillator 12, and a second connection state in which the inverter chain 151 is disconnected from the ring oscillator 12 to be connected to the function block 15. Specifically, the switch circuit 152 switches between the first connection state and the second connection state in accordance with a reset signal RST. When the reset signal RST is activated, the inverter chain 151 is disconnected from the function block 15 to be connected to the ring oscillator 12, the semiconductor integrated circuits 10_1-10_3 are in a degradation measurement mode. Note that the reset signal RST is preferably switched between activated and inactivated states at a predetermined time interval by controlling with a timer (not shown).

A power supply voltage determination section 101 receives outputs of the comparators 16 of the semiconductor integrated circuits 10_1-10_3, and determines degradation in characteristics of MOSFETs of the semiconductor integrated circuits 10_1-10_3. The power supply voltage determination section 101 determines power supply voltages to be supplied to the semiconductor integrated circuits 10_1-10_3 based on the determination result. The power supply voltage determination section 101 may be hardware or software. A power supply voltage supply section 102 controls voltages of the signals VDDs1-VDDs3 in accordance with the determination of the power supply voltage determination section 101 and supplies the voltages to the function blocks of the semiconductor integrated circuits 10_1-10_3. For example, when degradation in the characteristics of the MOSFET of the semiconductor integrated circuit 10_1 is determined to be larger than those of the other semiconductor integrated circuits 10_2 and 10_3, the power supply voltage supply section 102 lowers the voltage of the signal VDDs1, or sets the voltage to 0 V. Then, when the degradation in the characteristics of the MOSFET of the semiconductor integrated circuit 10_1 is determined to be improved, the power supply voltage supply section 102 sets the voltage of the signal VDDs1 to a normal power supply voltage, or lower power supply voltages to be supplied to the function blocks 15 of the other semiconductor integrated circuits 10_2 and 10_3.

As described above, in this embodiment, the power supply voltages supplied to the function blocks 15 of the semiconductor integrated circuits 10_1-10_3 are controlled in accordance with degradation in the characteristics of the MOSFETs of the semiconductor integrated circuits 10_1-10_3. This reduces degradation in the BTI to increase lifetime of the electronic device. Also, when each of the semiconductor integrated circuits 10_1-10_3 operates alone, the power supply voltage of the function block 15 can be maintained high, thereby enabling high-speed operation. Moreover, since margins of degradation in delay etc. can be reduced when designing the semiconductor integrated circuits 10_1-10_3, the sizes of the MOSFETs included in the semiconductor integrated circuits 10_1-10_3 can be reduced. This miniaturizes the semiconductor integrated circuits 10_1-10_3 and reduces power consumption.

What is claimed is:

1. A semiconductor integrated circuit comprising:
a first ring oscillator to which a stress voltage is applied;
a second ring oscillator to which the stress voltage is not applied; and
a phase comparator configured to receive an output of the first ring oscillator and an output of the second ring oscillator, and to compare phases of the outputs, wherein
the first ring oscillator includes a switch circuit configured to switch between a first connection state in which ring connection of the first ring oscillator is disconnected to connect a predetermined node of the second ring oscillator to a predetermined node of the first ring oscillator, and a second connection state in which connection between the first ring oscillator and the second ring oscillator is disconnected to connect the first ring oscillator in a ring.

2. The semiconductor integrated circuit of claim 1, further comprising
a current comparator configured to compare a current consumed in the first ring oscillator and a current consumed in the second ring oscillator, where supply of power supply voltages to the first and second ring oscillators is stopped.

3. The semiconductor integrated circuit of claim 1, wherein
the first and second ring oscillators are configured to control supply of power supply voltages independently from each other.

4. The semiconductor integrated circuit of claim 1, wherein
each of the first and second ring oscillators stops oscillating upon receipt of a reset signal.

5. The semiconductor integrated circuit of claim 1, wherein
the first ring oscillator includes a gate capacitor corresponding to an antenna wire included in the second ring oscillator.

6. The semiconductor integrated circuit of claim 1, wherein
the first and second ring oscillators include antenna wires having the same shapes.

7. An electronic device comprising:
a plurality of semiconductor integrated circuits;
a power supply voltage determination section; and
a power supply voltage supply section, wherein
each of the semiconductor integrated circuits includes
a ring oscillator,
a function block including an inverter chain,
a phase comparator configured to receive an output of the function block and an output of the ring oscillator, and to compare phases of the outputs, and
a comparator configured to compare an output of the phase comparator and a reference value,
the function block includes a switch circuit configured to switch between a first connection state in which the inverter chain is disconnected from the function block to be connected to a predetermined node of the ring oscillator, and a second connection state in which the inverter chain is disconnected from the ring oscillator to be connected to the function block,
the power supply voltage determination section determines a power supply voltage to be supplied to each of the plurality of semiconductor integrated circuits based on a comparison result of the comparator in each of the plurality of semiconductor integrated circuits, and
the power supply voltage supply section supplies a power supply voltage to the function block of each of the plurality of semiconductor integrated circuits in accordance with the determination of the power supply voltage determination section.
